(19) United States
(12) Patent Application Publication
(10) Pub. No.: US 2026/0314280 A1
(43) Pub. Date: Oct. 8, 2026

(54) IN SITU NUCLEATION OF DIAMOND FOR THERMAL CONDUCTIVE APPLICATIONS

(71) Applicants: Applied Materials, Inc., Santa Clara, CA (US); National University of Singapore, Singapore (SG)

(72) Inventors: Sze Chieh Tan, Singapore (SG); Nyi Myat Khine Linn, Singapore (SG); Vicknesh Sahmuganathan, Singapore (SG); John Sudijono, Singapore (SG); Rinku Saran, Singapore (SG); Utkur Mirsaidov, Singapore (SG)

(73) Assignees: Applied Materials, Inc., Santa Clara, CA (US); National University of Singapore, Singapore (SG)

(21) Appl. No.: 19/182,833

(22) Filed: Apr. 18, 2025

Related U.S. Application Data
(60) Provisional application No. 63/783,312, filed on Apr. 4, 2025.

(51) Int. Cl. H01L 21/02; C23C 16/27; C23C 16/455

(52) U.S. Cl. CPC H10P 14/6902; C23C 16/277; C23C 16/455; H10P 14/6532

(57) ABSTRACT

Methods of depositing microcrystalline diamond films with high thermal conductivity are described. The method may be used in the manufacture of high-power transistors, voltage regulators, central processing units (CPUs), graphics processing units (GPUs), chipsets, RAM modules, solid state drives (SSDs), and the like. Methods include treating a substrate with a mild plasma to form a treated substrate surface, incubating the treated substrate with a carbon-rich weak plasma to nucleate diamond particles on the treated substrate surface, followed by treating the substrate with a strong plasma to form a microcrystalline diamond film.

### CROSS-REFERENCE TO RELATED APPLICATION

This application claims priority to U.S. Provisional Application Ser. No. 63/783,312, filed Apr. 4, 2025, the entire disclosure of which is hereby incorporated by reference herein.

### TECHNICAL FIELD

Embodiments of the present disclosure pertain to the field of electronic device manufacturing, and, in particular, to integrated circuit (IC) manufacturing. More particularly, embodiments of the disclosure provide methods of depositing diamond films for thermal conductive applications.

### BACKGROUND

As the semiconductor industry introduces new generations of integrated circuits (ICs) having higher performance and greater functionality, the density of the elements that form those ICs is increased, while the dimensions, size, and spacing between the individual components or elements are reduced. While in the past, such reductions were limited only by the ability to define the structures using photolithography, device geometries having dimensions measured in μm or nm have created new limiting factors such as the conductivity of the metallic elements, the dielectric constant of the insulating material(s) used between the elements, or challenges in 3D-NAND or DRAM processes. These limitations may be addressed by more durable and higher hardness hard masks.

Diamond, with its superior hardness, chemical inertness, and high thermal conductivity, is a promising material for microelectronics. Challenges, however, such as the large difference in surface energies between diamond and silicon, low sticking coefficients of gaseous precursors, and competition from non-diamond phases result in poor diamond nucleation on untreated silicon. To address poor diamond nucleation density, the substrate is usually pre-treated (e.g., mechanical abrasion or micro-chipping) and/or seeded with diamond particles prior to deposition. Such seeding methods, however, consist of multiple solution-based procedures which are cumbersome and not cleanroom compatible. Bias-enhanced nucleation (BEN) offers an in situ alternative, using ionized gas species to form a carbide layer with better adhesion. Despite achieving high nucleation densities, BEN has limitations like substrate damage, difficulty in uniform bias application, and the need for conductive substrates.

There is a need, therefore, for improved processes for the deposition of crystalline diamond films having high thermal conductivity.

### SUMMARY

One or more embodiments of the disclosure are directed to a method of forming film. In one or more embodiments, the method comprises: exposing a substrate to a first plasma from a plasma source with a first plasma power in a range of from 10 W to 20,000 W, the first plasma source comprising one or more of CₓH_{y} wherein y≥x, oxygen (O₂), carbon dioxide (CO₂), hydrogen (H₂), nitrogen (N₂), and argon (Ar) to provide a treated substrate; incubating the treated substrate with a gas stream and a second plasma to nucleate diamond particles on a top surface of the substrate, the gas stream comprising from 3% to 98% hydrocarbon and the second plasma having a power less than or equal to 15 kW; and exposing the diamond particles to a third plasma having a power greater than 50 W to form a microcrystalline diamond film on the top surface of the substrate, the microcrystalline diamond film having a grain size in a range of from 5 nm to 2 μm and a seed density in a range of from 10⁵/cm² to 10¹¹/cm².

Other embodiments of the disclosure are directed to a method of forming a diamond film. In one or more embodiments, the method comprises: exposing a hydrocarbon plasma treated substrate to a gas stream to nucleate diamond particles on a top surface of the hydrocarbon plasma treated substrate, the gas stream comprising a hydrocarbon; and exposing the diamond particles to a microwave plasma having a power greater than 50 W to form a microcrystalline diamond film on the top surface of the hydrocarbon plasma treated substrate, the microwave plasma having a duty cycle greater than or equal to 60%, the microcrystalline diamond film having a grain size in a range of from 5 nm to 2 μm and a seed density in a range of from 10⁵/cm² to 10¹¹/cm².

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments, as described herein, are illustrated by way of example and are not limited in the figures of the accompanying drawings in which like references indicate similar elements.

FIG. 1 illustrates a process flow diagram of a method for depositing a crystalline diamond film according to one or more embodiments;

FIG. 2A illustrates a schematic cross-sectional view of a substrate during the method according to one or more embodiments;

FIG. 2B illustrates a schematic cross-sectional view of a substrate during the method according to one or more embodiments;

FIG. 2C illustrates a schematic cross-sectional view of a substrate during the method according to one or more embodiments;

FIG. 2D illustrates a schematic cross-sectional view of a substrate during the method according to one or more embodiments; and

FIG. 2E illustrates a schematic cross-sectional view of a substrate during the method according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor”, “reactant”, “reactive gas”, and the like are used interchangeably to refer to any gaseous species that can react with the substrate surface.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used herein, the phrase “polycrystalline diamond” refers to a solid film of synthetic diamond having small diamond crystals grown together, forming a film on a substrate. Polycrystalline diamond may contain both nanocrystalline and microcrystalline diamond particles at various compositions. Nanocrystalline diamond has grain sizes less than 100 nm. Microcrystalline diamond has grain sizes larger than 100 nm. Polycrystalline diamond is a synthetic material made by sintering diamond particles under high pressure and temperature, and is known for its hardness, wear resistance, and thermal conductivity. The thermal conductivity of polycrystalline diamond ranges from few tens of W/m·K to around 1500 W/m·K depending on growth conditions and the composition of nano- and microcrystalline diamonds in it.

The diamond film formed by one or more embodiments is a microcrystalline diamond film. As used herein, the phrase “microcrystalline diamond” refers to a solid film of diamond having a grain size in the micrometer range, grown on a substrate. In one or more embodiments, the microcrystalline diamond film has a large grain size, specifically a grain size in a range of from 0.1 μm to 100 μm. One or more embodiments provide a microcrystalline diamond film having high hardness and high thermal conductivity. In one or more embodiments, the thermal conductivity is in a range of from 10 W/mK to 2000 W/mK, including in a range of from 200 W/mK to 500 W/mK. In one or more embodiments, the microcrystalline diamond film has seed and grain sizes in a range of from 5 nm to 2 μm and a seed density in a range of from 10⁵/cm² to 10¹¹/cm². In some specific embodiments, the microcrystalline diamond has a grain size between 700 nm to 2000 nm and ID/IG ratio, which is an indication of SP3/SP2 content, of from between 2 and 50.

As used herein, the phrase “nanocrystalline diamond” refers to a solid film of diamond typically grown on a substrate, such as silicon. Nanocrystalline diamond layers are comprised of small diamond crystals in nanospheres, or a nanocolumnar shape, and amorphous carbon distributed usually distributed in the positions between surrounding crystals or accumulate in the grain boundaries. Nanocrystalline diamond is used as a hard mask material in semiconductor applications because of its chemical inertness, optical transparency, and good mechanical properties. Nanocrystalline diamond has a particle size in a range of from 1 nm to 100 nm. Nanocrystalline diamond materials have a small grain size, specifically a grain size in a range of from 1 nm to 100 nm. Nanocrystalline diamond materials have a thermal conductivity in a range of from >0 W/mK to 15 W/mK, including in a range of from >0 W/mK to 10 W/mK.

The increasing power demands of electronic applications, including 5G/6G, have made thermal management crucial. Joule heating in the device channel due to higher power leads to performance degradation and early failure. To address this, enhancing heat transfer using thermally conductive materials is critical. Owing to its excellent thermal conductivity (TC) (TC>2000 W/m·K), diamond, specifically microcrystalline diamond, can be used for heat spreading out of the channel through the backside by wafer bonding or growth and through the top side by direct microcrystalline diamond growth which provides a much lower thermal resistance. Diamond integration onto the device's top, near the channel, can be achieved through direct chemical vapor deposition. For instance, direct diamond growth on GaN-based high-electron-mobility transistors was previously reported, in which they have shown promising results with the diamond as it reduced the channel temperature and lowered the self-heating effect on drain current. Devices that generate significant amount of heat require the use of thermal conductive materials to dissipate heat. Some examples of these such devices include, but are not limited to, high-power transistors, voltage regulators, central processing units (CPUs), graphics processing units (GPUs), chipsets, RAM modules, solid state drives (SSDs), and the like.

Since the diamond crystal structure is distorted at the grain boundaries (GBs), it affects the phonon dispersion relation and reduces the thermal conductivity of diamond. To enable a highly conductive lateral thermal path through the diamond layer, an enhancement in its in-plane thermal conductivity, along with negligible thermal boundary resistances between diamond and channel/junction material at the interface, is required. The two important parameters to enhance in-plane thermal conductivity are (1) grains with larger lateral dimensions or less GB densities and (2) higher sp³ phase purity for higher in-grain thermal conductivity.

One or more embodiments advantageously describe the development of diamond seeds in plasma and the process growth tuned towards achieving high thermal conductivity, thereby eliminating need for wet-procedures and allowing subsequent integration steps. One or more embodiments of the disclosure advantageously provide a method for the in-situ nucleation and growth of microcrystalline diamond films. Embodiments describe the development and utilization of plasma and gas chemistry for substrate treatment and the nucleation and growth of microcrystalline diamond films. In one or more embodiments, prior solution-based substrate treatment/cleaning nor additional seeding methods such as sonication with diamonds or mechanical scratching are not required. Likewise, no unique chemicals are required during the process.

Conventionally, a semiconductor substrate is pre-treated and/or seeded with diamonds prior to deposition. Such seeding methods, however, consist of solution-based procedures which are cumbersome and not cleanroom compatible. Bias-enhanced nucleation is one of the few nucleation techniques that can be performed in-situ, but it causes substrate damages and have poor uniformity. One or more embodiments deposits highly thermal conductive diamond uniformly without damaging the substrate.

In one or more embodiments, a microcrystalline diamond layer is formed on a substrate. The process of one or more embodiments advantageously produces a microcrystalline diamond layer with high density, high hardness, high etch selectivity, low stress, and excellent thermal conductivity.

In one or more embodiments, a breakthrough in diamond growth has been advantageously achieved through in situ nucleation, demonstrating comparable or superior characteristics to traditional solution-seeding methods. The resulting diamond exhibits high sp³ purity (high ID/IG ratio) and ultra-large grain sizes, indicating potential for thermal conductivity surpassing that of solution-seeded diamond. The in situ nucleation process of one or more embodiments offers flexibility in utilizing various hydrocarbons and optimizing process conditions, enabling the growth of diamond films with highly tunable properties (one of the properties being thermal conductivity (TC)).

The method of one or more embodiments presents a novel approach for growing microcrystalline diamond for thermal conductive applications, including as heat dissipation layers in devices.

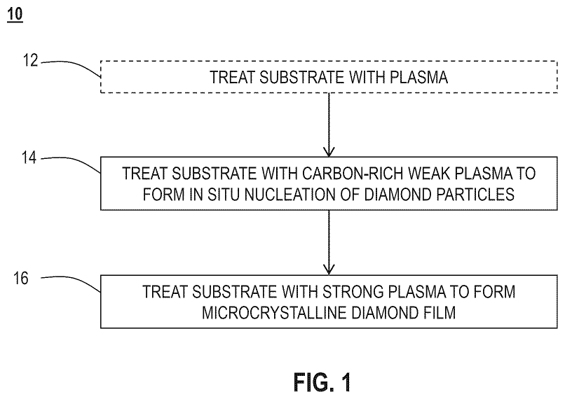

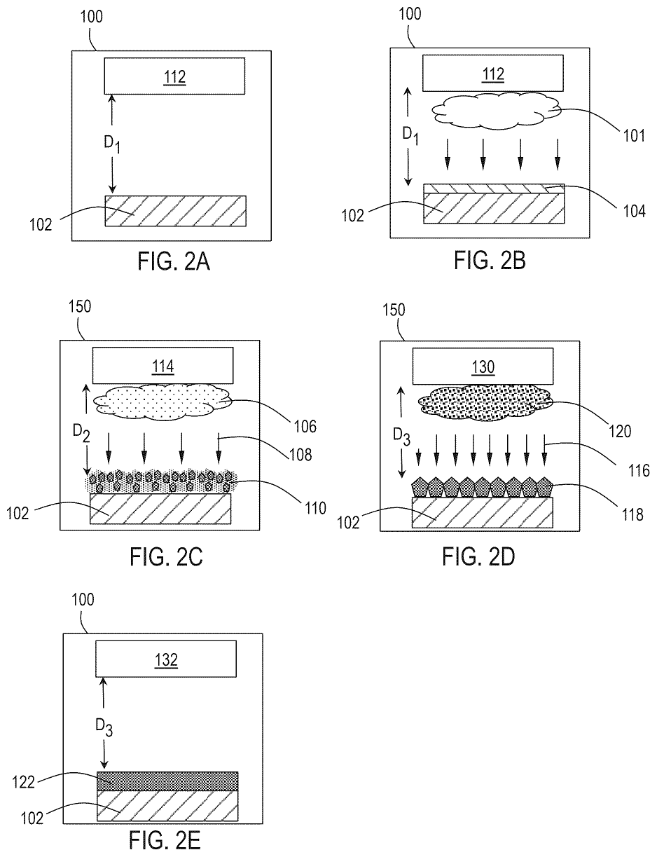

One or more embodiments of the disclosure are described with reference to the Figures. FIG. 1 illustrates a process flow diagram of a method 100 according to one or more embodiments. FIGS. 2A through 2E illustrate schematic cross-sectional views of a substrate 102 being processed according to the method of one or more embodiments.

Referring to FIGS. 1 and 2A-2B, a method 10 of forming a microcrystalline diamond film 122 is described. In some embodiments, the method 10 comprises, at operation 12, treating a substrate 102 with a plasma 101 from a plasma source 112 to form a treated substrate surface 104. The substrate 102 surface is exposed to a mild first plasma 101 in the first plasma process chamber 100 for a first plasma time period T_{P1} to form treated or pre-treated substrate surface 104.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the molybdenum-containing layer, for example, by polishing, etching, reduction, oxidation, halogenation, hydroxylation, annealing, baking, or the like.

The substrate may be any substrate capable of having material deposited thereon, such as a silicon substrate, a silicon-based substrate, a germanium-based substrate, a gallium-based substrate, a metal substrate, a II-VI compound substrate, a III-V compound substrate, and their respective compound, oxide and nitride substrates. In other embodiments, the substrate may include a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. Substrates, herein, may be chemically and/or physically unmodified or modified.

In some embodiments, one or more additional layers may be disposed on the substrate such that the polymerizable seed layer may be at least partially formed thereon. For example, in some embodiments, a layer comprising a metal, a nitride, an oxide, or the like, or combinations thereof may be disposed on the substrate and may have the polymerizable seed layer formed upon such layer or layers. In one or more embodiments, the substrate comprises silicon (Si) or poly-silicon (p-Si). In some embodiments, the substrate comprises a poly-silicon substrate. In some embodiments, the substrate is chemically and/or physically unmodified.

The first plasma process chamber 100 can be any suitable plasma chamber with any suitable plasma source, such as, but not limited to, remote, microwave, capacitively coupled plasma (CCP), or inductively coupled plasma (ICP). In some embodiments, flow rates and other processing parameters described below are for a 300 mm substrate. It should be understood that these parameters can be adjusted based on the size of the substrate processed and the type of chamber used without diverging from the embodiments disclosed herein. In specific embodiments, the mild first plasma 101 comprises one or more of a capacitively coupled plasma, inductively coupled plasma, pulsed discharge plasma, microwave plasma, hot filament, or electron cyclotron resonance plasma.

In some embodiments, the first plasma 101 comprises one or more of an organic species having the empirical formula CₓH_{y} where y≥x, argon (Ar), molecular nitrogen (N₂), carbon dioxide (CO₂), oxygen (O₂), or molecular hydrogen gas (H₂). The gases may be co-flowed, flow separately and/or be flowed in different combinations in single or multi-step process.

In some embodiments, the first plasma 101 is generated with a power greater than 10 watts, 100 watts, or 1000 watts. In one or more embodiments, the plasma treatment may occur at any suitable power. In one or more embodiments, the power is greater than 10 W. In other embodiments, the power is in a range of from 10 W to 20,000 W, or in a range of from 100 W to 20,000 W, or in a range of from 500 W to 20,000 W.

In some embodiments, the substrate 102 is maintained at a temperature in the range of from 20° C. to 600° C. during formation of the treated substrate surface 104.

In some embodiments, forming the treated substrate surface 104 comprises more than one cycle of exposure to the mild first plasma 101. In some embodiments, forming the treated substrate surface 104 comprises in the range of 1 to 1000 cycles of exposures to the mild first plasma 101.

The first plasma process chamber 100 of some embodiments comprises a first plasma source 112, which may include one or more of a showerhead, electrodes, resonators, linear antenna, and the like. In one or more embodiments, the first plasma source 112 is positioned at a first distance D₁ from the top surface of the substrate 102. In some embodiments, the first distance, D₁, is greater than or equal to 0.5 mm, or greater than or equal to 5 mm, or greater than or equal to 10 mm, or greater than or equal to 15 mm.

Referring to FIG. 1 and FIG. 2C, at operation 14, the treated substrate 104 is incubated with a carbon-rich gas stream 108 and a second plasma 106 to nucleate diamond particles forming a diamond nuclei layer 110 on the top surface of the substrate 102.

In one or more embodiments, the diamond nuclei layer 110 is formed in a second plasma process chamber 150 with a second mild plasma 106 generated by a plasma source 114. In other embodiments, the diamond nuclei layer 110 is formed in the first plasma process chamber 100 with a second mild plasma 106 generated by a plasma source 114. In some embodiments, the second mild plasma 106 can be generated by the first plasma source 112 but using different gases (compositions).

The second plasma process chamber 150 and the first process chamber 100 can be any suitable plasma chamber with any suitable plasma source, such as, but not limited to, remote, microwave, capacitively coupled plasma (CCP), or inductively coupled plasma (ICP). In some embodiments, flow rates and other processing parameters described below are for a 300 mm substrate. It should be understood that these parameters can be adjusted based on the size of the substrate processed and the type of chamber used without diverging from the embodiments disclosed herein. In specific embodiments, the mild second plasma 106 comprises one or more of a capacitively coupled plasma, inductively coupled plasma, pulsed discharge plasma, microwave plasma, hot filament, or electron cyclotron resonance plasma.

In some embodiments, the gas stream 108 and second mild plasma 106 comprises a hydrocarbon. In one or more embodiments, the hydrocarbon has a general formula of CₘHₙ, where m is in a range from 1 to 120, and n is in a range of from 2 to 242. In specific embodiments, the hydrocarbon is selected from one or more of methane (CH₄), ethane (C₂H₆), propane (C₃H₈), butane (C₄H₁₀), pentane (C₅H₁₂), hexane (C₆H₁₄), heptane (C₇H₁₆), ethene (C₂H₄), propene (C₃H₆), butene (C₄H₈), pentene (C₅H₁₀), hexene (C₆H₁₂), heptane (C₇H₁₄), ethyne (C₂H₂), propyne (C₃H₄), butyne (C₄H₆), pentyne (C₅H₈), hexyne (C₆H₁₀), and heptyne (C₇H₁₂).

In one or more embodiments, the second mild plasma 106 may include, in addition to the hydrocarbon, one or more of oxygen (O₂), argon (Ar), molecular nitrogen (N₂), carbon dioxide (CO₂), or molecular hydrogen gas (H₂). In one or more embodiments, the gas stream 108 comprising the hydrocarbon is co-flowed with one or more of oxygen (O₂), argon (Ar), molecular nitrogen (N₂), carbon dioxide (CO₂), or molecular hydrogen gas (H₂) during plasma generation. The gases may be co-flowed, flow separately and/or be flowed in different combinations in single or multi-step process.

In one or more embodiments, the gas stream 108 and the second mild plasma 106 comprise from 3% to 98% hydrocarbon, or from 5% to 90% hydrocarbon.

In some embodiments, the second mild plasma 106 is generated with a power less than or equal to 15 kilowatts (KW), 12 kW, 10 kW, 9 kW, 8 kW, 7 kW, 6 KW, 5 kW, or 4 kW. In some embodiments, the gas stream 108 is ignited at a power of less than 12 kW to form the second mild plasma 106. In some embodiments, the second mild plasma 106 is a pulsed plasma with a duty cycle less than or equal to 100%, 95%, 90%, 85%, 80%, 75%, 70%, 65% or 60% at a frequency in the range of 50 Hz to 100 Hz, or in the range of 60 Hz to 90 Hz, or in the range of 70 Hz to 80 Hz. In some embodiments, the second mild plasma 106 has a power less than or equal to 6 kW with a duty cycle less than or equal to 50% at a frequency in the range of 70 Hz to 80 Hz. In some embodiments, the substrate 102 is maintained at a temperature in the range of 50° C. to 450° C. formation of the diamond nuclei layer 110. In one or more embodiments, the treated substrate is maintained at a temperature of less than 450° C. during incubation.

In some embodiments, the treated substrate 104 is incubated with the gas stream 108 and the second mild plasma 106 for a time period in a range of from 1 second to 14,400 seconds. In some embodiments, the treated substrate 104 is incubated with the gas stream 108 and the second mild plasma 106 for a time period of less than 4 hours, or less than 3 hours, or less than 2 hours, or less than 1 hour.

In some embodiments, the substrate 102 is positioned at a second distance D₂ from the plasma source 114. In one or more embodiments, the second mild plasma 106 can be generated by the first plasma source 112 but using different gases (compositions). In some embodiments, the substrate 102 is positioned at a second distance D₂ less than or equal to 12 cm, 11 cm, 10 cm, 9 cm, or 8 cm from the second plasma source 114 or from the first plasma source 112. In some embodiments, the second plasma source 114 or the first plasma source 112 comprises a showerhead which acts as an electrode. In some embodiments, the first plasma source 112 or the second plasma source 114 comprises a microwave plasma source.

At operation 16, a full microcrystalline diamond film 118 is grown from the diamond nuclei layer 110. As used in this manner, the term “grown” means that the full microcrystalline diamond film 118 is formed on the diamond nuclei layer 110 and may incorporate the diamond nuclei layer 110 into the full microcrystalline diamond film 118. The full microcrystalline diamond film 118 can be epitaxially grown or deposited by any suitable technique known to the skilled artisan.

In some embodiments, growing the full microcrystalline diamond film 118 occurs in the second plasma process chamber 150 using a strong plasma 120. In other embodiments, growing the full microcrystalline diamond film 118 occurs in the first plasma process chamber 100 using a strong plasma 120. Thus, in one or more embodiments, the first plasma process chamber 100 and the second plasma process chamber 150 are the same chamber. In some embodiments, the full microcrystalline diamond film 118 is grown using a strong conductively or inductively coupled plasma, microwave plasma, pulsed discharge plasma, hot filament, or electron cyclotron resonance plasma. In some embodiments, the full microcrystalline diamond film 118 is grown using a strong microwave plasma.

In some embodiments, the strong plasma 120 comprises a microwave plasma having a power greater than or equal to 1 kW, 3 kW, 4 kW or 5 kW with a duty cycle greater than or equal to 60%, 65%, 70%, 75% or 80%. In one or more embodiments, the strong plasma 120 comprises a hydrocarbon. The hydrocarbon has a general formula of CₒHₚ, where o is in a range from 1 to 120, and p is in a range of from 2 to 242. In specific embodiments, the hydrocarbon is selected from one or more of methane (CH₄), ethane (C₂H₆), propane (C₃H₈), butane (C₄H₁₀), pentane (C₅H₁₂), hexane (C₆H₁₄), heptane (C₇H₁₆), ethene (C₂H₄), propene (C₃H₆), butene (C₄H₈), pentene (C₅H₁₀), hexene (C₆H₁₂), heptane (C₇H₁₄), ethyne (C₂H₂), propyne (C₃H₄), butyne (C₄H₆), pentyne (C₅H₈), hexyne (C₆H₁₀), and heptyne (C₇H₁₂).

In one or more embodiments, in addition to the hydrocarbon, the strong plasma 120 may include one or more of argon (Ar), molecular nitrogen (N₂), carbon dioxide (CO₂), molecular hydrogen (H₂) gas, or molecular oxygen (O₂). The gases may be co-flowed, flow separately and/or be flowed in different combinations in single or multi-step process.

In some embodiments, the substrate 102 is maintained at a temperature in the range of room temperature (25° C.) to 750° C. during exposure to the microwave strong plasma 120. In some embodiments, the substrate 102 is maintained at a temperature greater than room temperature (25° C.), 50° C., 75° C., 100° C., 150° C., 200° C., or 250° C. during exposure to the microwave strong plasma 120.

During operation 16, the substrate 102 is positioned a distance D₃ from the third plasma source 130. In other embodiments, the strong plasma 120 can be generated by the first plasma source 112 and/or the second plasma source 114 but using different gases (compositions) or by a different third plasma source 130. In some embodiments, the distance D₃ is the same as the distance D₂. In some embodiments, the third distance D₃ is less than the second distance D₂. In some embodiments, the substrate 102 is positioned at a distance from the strong microwave plasma source 130, or from the first plasma source 112 or from the second plasma source 114, of less than 12 cm, 11 cm, 10 cm, 9 cm, or 8 cm.

With reference to FIG. 2E, in one or more embodiments, after being subjected to an extended period of main growth, the high nucleation density on the plasma-treated substrate 102 led to the formation of a fully coalesced crystalline diamond film 1222. In one or more embodiments, FIG. 2E illustrates how the fully coalesced crystalline diamond film 122 looks after the entire process is completed. The difference between microcrystalline diamond film 118 and fully coalesced microcrystalline diamond film 122 is that in the microcrystalline diamond film 118, the diamond nuclei from diamond nuclei layer 110 grow in size to become individual, larger diamond particles. These larger diamond particles are, however, isolated from each other. As these large diamond particles continue to grow in size, they eventually come into contact with the neighboring particles and begin to merge/coalesce with each other. This forms a dense, packed crystalline diamond film, which becomes the fully coalesced microcrystalline diamond film 122.

In one or more embodiments, the fully coalesced microcrystalline diamond film 122 has grains with large lateral dimensions and high sp³ phase purity for higher in-grain thermal conductivity. In one or more embodiments, the fully coalesced microcrystalline diamond film 122 has a seed density in a range of from 10⁵/cm² to 10¹¹/cm² (10⁵ per cm² to 10¹¹ per cm²). In one or more embodiments, the fully coalesced microcrystalline diamond film 122 has a grain size in a range of from 5 nm to 2 μm, including 5 nm, 50 nm, 100 nm, 200 nm, 300 nm, 400 nm, 500 nm, 600 nm, 700 nm, 800 nm, 900 nm, 1000 nm, 1010 nm, 1050 nm, 1100 nm, 1200 nm, 1300 nm, 1400 nm, 1500 nm, 1600 nm, 1700 nm, 1800 nm, 1900 nm, and 2000 nm.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Comparative

A silicon wafer was pre-treated in a hot chemical bath to remove organic contaminants. The cleaned silicon wafer was then sonicated in a premixed nanodiamond particle solution for an extended period. This procedure allowed the nanodiamond particles, also known as “diamond seeds,” to adhere onto the silicon substrate. The “seeded substrate” was then loaded into a conductively or inductively coupled plasma, microwave plasma, pulsed discharge plasma, hot filament, or electron cyclotron resonance plasma chamber for a growth process. A CₓH_{y}, argon (Ar), oxygen (O₂), nitrogen (N₂), carbon dioxide (CO₂), and/or hydrogen gas (H₂) plasma greater than 50 W and 50% duty cycle was applied for the growth of the diamond seeds into crystalline diamond film. This growth process was conducted at a stage temperature between 100-750° C., and at a gap of less than 10 cm. The stage temperature was maintained between 20-600° C. throughout the entire process and the gap between the stage and plasma source was greater than 0.5 mm.

### Example 2: Carbon-Rich Incubation to Form Microcrystalline Diamond

A silicon wafer was loaded into a conductively or inductively coupled plasma, microwave plasma, pulsed discharge plasma, hot filament, or electron cyclotron resonance plasma chamber and pre-cleaned/treated with a mild CₓH_{y}, argon (Ar), oxygen (O₂), nitrogen (N₂), carbon dioxide (CO₂), and/or hydrogen gas (H₂) plasma greater than 10 W to prepare a treated substrate. The stage temperature was maintained between 20-600° C. throughout the entire process and the gap between the stage and plasma source was greater than 0.5 mm.

The plasma-treated wafer was then subjected to an incubation process for the in-situ nucleation of diamond particles. During incubation, a carbon-rich gas mixture comprising of 3-98% of methane (CH₄), ethane (C₂H₆), propane (C₃H₈), butane (C₄H₁₀), pentane (C₅H₁₂), hexane (C₆H₁₄), heptane (C₇H₁₆), ethene (C₂H₄), propene (C₃H₆), butene (C₄H₈), pentene (C₅H₁₀), hexene (C₆H₁₂), heptane (C₇H₁₄), ethyne (C₂H₂), propyne (C₃H₄), butyne (C₄H₆), pentyne (C₅H₈), hexyne (C₆H₁₀) and/or heptyne (C₇H₁₂) was supplied to ensure sufficient carbon source for the nucleation of diamond particles. This was conducted under a relatively weak plasma power of less than 12 kW, 100% duty cycle and 75 Hz, for less than 4 hours. The stage temperature was below 450° C., and the gap was maintained between 2 to 10 cm.

Thereafter, a stronger plasma greater than 50 W and 50% duty cycle was applied for the growth of the diamond particles into crystalline diamond film. This main growth process was conducted at a stage temperature between 100-750° C., and at a gap of less than 10 cm.

The thermal conductivity of the wet-seeded (Example 1), plasma-treated microcrystalline diamond (Example 2) after incubation and main growth process, and a commercially available nanocrystalline diamond (Example 3) was compared. The samples were characterized by scanning electron microscopy (SEM) and Raman measurement (325 nm laser). It was observed that under identical process conditions, significantly greater thermal conductivity was achieved on plasma-treated microcrystalline diamond (Example 2) as compared to the wet-seeded (Example 1) and commercially available nanocrystalline diamond (Example 3).

TABLE 1

| | Thermal Conductivity | | |
|---|---|---|---|
| | (W/mK) | | Grain Size |
| Comparative Example 1 | 52 | W/m · K | 400 nm to 1500 nm |
| Example 2 | 10 to ≥2000 | W/m · K | 700 nm to 2000 nm |
| Comparative Example 3 | 10 to 15 | W/mK | ~25 nm |

After being subjected to an extended period of main growth, the plasma-treated microcrystalline diamond (Example 2) led to the formation of a fully coalesced crystalline diamond film. The morphologies and Raman measurement of a crystalline diamond film grown by the in-situ nucleation method are also comparable to that of a ND-seeded wafer prepared by the conventional solution-based seeding. Film properties such as refractive index, extinction coefficient, roughness, hardness and modulus were validated to be comparable to that of the wet-seeded samples.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of forming film, the method comprising:
exposing a substrate to a first plasma from a plasma source with a first plasma power in a range of from 10 W to 20,000 W, the first plasma comprising one or more of CₓH_{y} wherein y≥x, oxygen (O₂), carbon dioxide (CO₂), hydrogen (H₂), nitrogen (N₂), and argon (Ar) to provide a treated substrate;
incubating the treated substrate with a gas stream and a second plasma to nucleate diamond particles on a top surface of the substrate, the gas stream comprising from 3% to 98% hydrocarbon and the second plasma having a power less than or equal to 15 kW; and
exposing the diamond particles to a third plasma having a power greater than 50 W to form a microcrystalline diamond film on the top surface of the substrate, the microcrystalline diamond film having a grain size in a range of from 5 nm to 2 μm and a seed density in a range of from 10⁵ per cm² to 10¹¹ per cm².

2. The method of claim 1, wherein the hydrocarbon has a general formula of CₘHₙ, where m is in a range of from 1 to 120, and n is in a range of from 2 to 242.

3. The method of claim 2, wherein the gas stream further comprises one or more of oxygen (O₂), carbon dioxide (CO₂), hydrogen (H₂), nitrogen (N₂), and argon (Ar).

4. The method of claim 1, wherein the gas stream is ignited at a power of less than 12 kW.

5. The method of claim 1, wherein the treated substrate is incubated with the gas stream and the second plasma for a time period of less than 4 hours.

6. The method of claim 1, wherein the treated substrate is maintained at a temperature of less than 450° C. during incubation.

7. The method of claim 1, wherein the diamond particles are maintained at a temperature in a range of from 100° C. to 750° C. during formation of the microcrystalline diamond film.

8. The method of claim 1, wherein incubating the treated substrate is conducted with a duty cycle of less than or equal to 100%.

9. The method of claim 1, wherein the third plasma has a duty cycle greater than 50%.

10. The method of claim 1, wherein the first plasma has a power in a range of from 10 W to 20,000 W.

11. The method of claim 1, wherein the substrate is exposed to the first plasma at a temperature in a range of from 20° C. to 600° C.

12. The method of claim 1, wherein the substrate is exposed to the first plasma at a distance of greater than 0.5 mm.

13. The method of claim 1, wherein when the treated substrate is incubated with the gas stream, the gas stream is about 2 cm to 10 cm away from the top surface of the treated substrate.

14. The method of claim 1, wherein when the diamond particles are exposed to the second plasma, the third plasma is less than 10 cm away from the top surface of the substrate.

15. The method of claim 1, wherein the diamond film has thermal conductivity values greater than or equal to a diamond film grown from a wet-seeded method.

16. A method of forming a diamond film, the method comprising:
exposing a hydrocarbon plasma treated substrate to a gas stream to nucleate diamond particles on a top surface of the hydrocarbon plasma treated substrate, the gas stream comprising a hydrocarbon; and
exposing the diamond particles to a microwave plasma having a power greater than 50 W to form a microcrystalline diamond film on the top surface of the hydrocarbon plasma treated substrate, the microwave plasma having a duty cycle greater than or equal to 60%, the microcrystalline diamond film having a grain size in a range of from 5 nm to 2 μm and a seed density in a range of from 10⁵ per cm² to 10¹¹ per cm².

17. The method of claim 16, wherein the hydrocarbon has a general formula of CₘHₙ, where m is in a range of from 1 to 120, and n is in a range of from 2 to 242.

18. The method of claim 17, wherein the gas stream further comprises one or more of oxygen (O₂), carbon dioxide (CO₂), hydrogen (H₂), nitrogen (N₂), and argon (Ar).

19. The method of claim 18, wherein the gas stream comprises from 3% to 98% of the hydrocarbon.

20. The method of claim 16, wherein the gas stream is ignited at a power of less than 12 kW.
